(19) United States
(12) Patent Application Publication
(10) Pub. No.: US 2009/0066259 A1
(43) Pub. Date: Mar. 12, 2009

(54) ORGANIC LIGHT EMITTING DIODE DEVICE AND METHOD FOR MANUFACTURING THE SAME

(76) Inventors: Young-In Hwang, Daegu (KR); Baek-Woon Lee, Yongin-si (KR)

Correspondence Address: MACPHERSON KWOK CHEN & HEID LLP, 2033 GATEWAY PLACE, SUITE 400, SAN JOSE, CA, 95110, US

(21) Appl. No.: 12/207,394

(22) Filed: Sep. 9, 2008

(30) Foreign Application Priority Data
Sep. 11, 2007 (KR) 10-2007-0091921

(51) Int. Cl. G09G 3/30; H01J 9/26

(52) U.S. Cl. 315/169.3; 445/24

(57) ABSTRACT

An organic light emitting diode device and a method of manufacturing the organic light emitting diode device are disclosed. The organic light emitting diode device includes a substrate, a switch thin film transistor on a first side of the substrate to perform a switching function and a driving thin film transistor on the first side of the substrate to perform a driving function, a pixel electrode electrically connected to the driving thin film transistor, a common electrode to form an electric field together with the pixel electrode, the common electrode corresponding to the pixel electrode, an organic light emitting layer disposed between the pixel electrode and the common electrode to generate light, a color filter overlapping the pixel electrode to convert the light generated from the organic light emitting layer into a prescribed color of light, and an absorption layer formed on a second side of the substrate facing the first side to absorb cyan spectrum of light.

### CROSS-REFERENCE TO RELATED APPLICATION

This application claims priority under 35 U.S.C. §119 to Korean Patent Application No. 10-2007-0091921, filed in the Korean Intellectual Property Office on Sep. 11, 2007, the disclosure of which is incorporated herein by reference in its entirety.

### BACKGROUND OF THE INVENTION

1. Field of the Invention

The present disclosure is directed to a field of an organic light emitting diode (OLED) device capable of improving the color gamut and a method of manufacturing the OLED device.

2. Description of the Related Art

The development of information technologies require more evolved display devices. As a consequence, flat panel displays including organic light emitting diode (OLED) displays are important due to their slim, compact design, which is in contrast to relatively heavy and bulky cathode ray tubes (CRTs). In this regard, the OLED device, a self light emissive display, may be made very slim, similar to a piece of paper.

An OLED device displays images using pixels consisting of three different color sub pixels, including a red sub pixel, a green sub pixel, and a blue sub pixel. Alternatively, the pixel may consist of four sub pixels by adding a white sub pixel to the three sub pixels. The OLED device includes a color filter (CF) that changes the color of the light generated from an organic light emission layer. For this purpose, the color filter splits the light into red, green, and blue components, each having a different spectrum. In this regard, the color filter should be thick so that the three split light components do not interfere with each other. The transmittance T has a relationship indicated by the following equation: T₀^{t′/t}, where T refers to a transmittance according to a variation in the thickness of the CF, T₀ refers to a reference transmittance, t′ refers to the calibrated thickness of the CF, and t refers to the thickness of the CF. Table 1, shown below, shows the thickness of the color filter used to attain the color gamut of 90% or 100%, which is calculated from the above equation, based on NTSC standard in 1931 chromaticity diagram.

TABLE 1

| | Thickness of | Thickness of | Thickness of | |
|---|---|---|---|---|
| Color gamut | Red CF | Green CF | Blue CF | Remarks |
| 73% | 100% | 100% | 100% | Current |
| | | | | thickness of CF |
| 90% | 100% | 179% | 179% | |
| 100% | 100% | 283% | 283% | |

However, the thick color filter may sharply degrade the brightness and efficiency of the OLED device, since the transmittance may be lowered.

### SUMMARY OF THE INVENTION

In one embodiment, an OLED device capable of improving color gamut by separating a blue spectrum of light from a green spectrum of light without any loss of brightness and efficiency, and a method of manufacturing the OLED device is described.

One embodiment provides an organic light emitting diode device comprising: a substrate, a switch thin film transistor on a first side of the substrate to perform a switching function and a driving thin film transistor on the first side of the substrate to perform a driving function, a pixel electrode electrically connected to the driving thin film transistor, a common electrode to form an electric field together with the pixel electrode, the common electrode corresponding to the pixel electrode, an organic light emitting layer disposed between the pixel electrode and the common electrode to generate light, a color filter overlapping the pixel electrode to convert the light generated from the organic light emitting layer into a prescribed color of light, and an absorption layer formed on a second side of the substrate facing the first side to absorb a cyan spectrum of light.

The absorption layer may absorb light whose wavelength ranges from about 470 nm to about 520 nm.

The absorption layer may contain a dye or pigment that absorbs light whose wavelength ranges from about 470 nm to about 520 nm.

The absorption layer may be formed by attaching a high molecular film on which the dye or pigment has been coated to the substrate.

The absorption layer may be formed by coating a solution containing the dye or pigment on the substrate.

The organic emission layer may generate white light.

Another embodiment provides an organic light emitting diode device comprising: a substrate formed to absorb cyan spectrum of light, a switch thin film transistor on a first side of the substrate to perform a switching function and a driving thin film transistor on the first side of the substrate to perform a driving function, a pixel electrode electrically connected to the driving thin film transistor, a common electrode to form an electric field together with the pixel electrode, the common electrode corresponding to the pixel electrode, an organic light emitting layer disposed between the pixel electrode and the common electrode to generate light, and a color filter overlapping the pixel electrode to convert the light generated from the organic light emitting layer into a prescribed color of light.

Another embodiment provides a method of manufacturing an organic light emitting diode device, the method comprising: forming a switch thin film transistor to perform a switching function and a driving thin film transistor to perform a driving function on a first side of a substrate, forming a protective layer on the substrate to protect the switch thin film transistor and the driving thin film transistor, forming a color filter on the protective layer, forming an organic light emitting diode on the color filter, the organic light emitting diode comprising a pixel electrode electrically connected to the driving thin film transistor, an organic light emitting layer disposed on the pixel electrode to generate light, and a common electrode to form an electric field together with the pixel electrode, the common electrode corresponding to the pixel electrode, and forming an absorption layer on a second side of the substrate facing the first side to absorb cyan spectrum of light.

In one embodiment, forming the absorption layer comprises forming the absorption layer using a dye or pigment to absorb a cyan spectrum of light.

In another embodiment, forming the absorption layer comprises forming the absorption layer by attaching on the substrate a high molecular film on which the dye or pigment has been coated.

In still another embodiment, forming the absorption layer comprises forming the absorption layer by coating a solution containing the dye or pigment on the substrate.

Another embodiment provides a method of an organic light emitting diode device comprising: forming a substrate that absorbs a cyan spectrum of light, forming a switch thin film transistor to perform a switching function and a driving thin film transistor to perform a driving function on a first side of the substrate, forming a protective layer on the substrate to protect the switch thin film transistor and the driving thin film transistor, forming a color filter on the protective layer, and forming an organic light emitting diode on the color filter, the organic light emitting diode comprising a pixel electrode electrically connected to the driving thin film transistor, an organic light emitting layer disposed on the pixel electrode to generate light, and a common electrode to form an electric field together with the pixel electrode, the common electrode corresponding to the pixel electrode.

In one embodiment, forming the substrate comprises forming the substrate by making the substrate contain a dye or pigment that absorbs a cyan spectrum of light.

### BRIEF DESCRIPTION OF THE DRAWINGS

The above and other features of the disclosure will be described in reference to various embodiments thereof with reference to the attached drawings in which:

FIG. 1 is a plan view illustrating an OLED device according to one embodiment;

FIG. 2A is a cross-sectional view taken along the line I-I′ of FIG. 1;

FIG. 2B is cross sectional view taken along the line II-II′ of FIG. 1;

FIG. 3 is a cross sectional view taken along the line I-I′ of FIG. 1 according to another embodiment;

FIG. 4A is a graph illustrating spectrums and color gamut of light that have passed through a color filter;

FIG. 4B is a chromaticity diagram illustrating spectrums and color gamut of light that have passed through a color filter;

FIG. 5 is a graph illustrating a relationship of transmittance and wavelength of an absorption layer according to one embodiment;

FIG. 6A is a graph illustrating spectrums and color gamut of light that have passed through a color filter and an absorption layer according to one embodiment;

FIG. 6B is a chromaticity diagram illustrating spectrums and color gamut of light that have passed through a color filter and an absorption layer according to another embodiment;

FIGS. 7A and 7B are chromaticity diagrams illustrating the brightness and efficiency of a color filter based on 90% color gamut according to another embodiment; and

FIGS. 8A and 8B are chromaticity diagrams illustrating the brightness and efficiency of a color filter based on 100% color gamut according to another embodiment.

### DETAILED DESCRIPTION

The subject matter now will be described more fully hereinafter with reference to the accompanying drawings, in which various embodiments are shown. The subject matter described herein may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings provided herein.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “includes” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, various embodiments should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the disclosure.

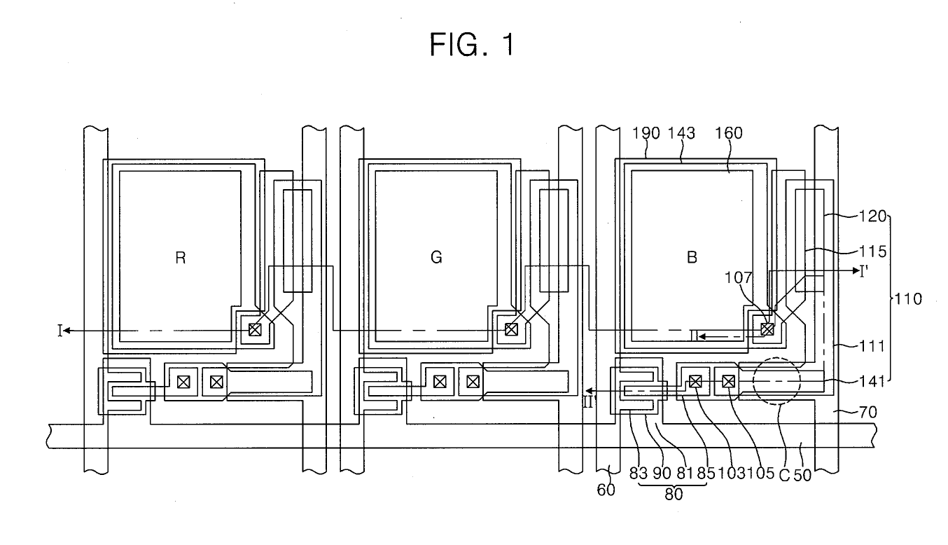

Hereinafter, various embodiments will be described with reference to FIGS. 1 through 8B.

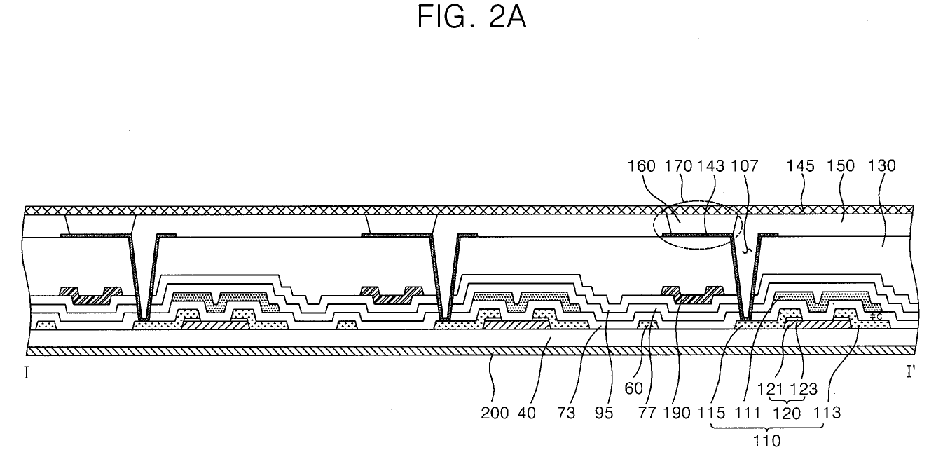

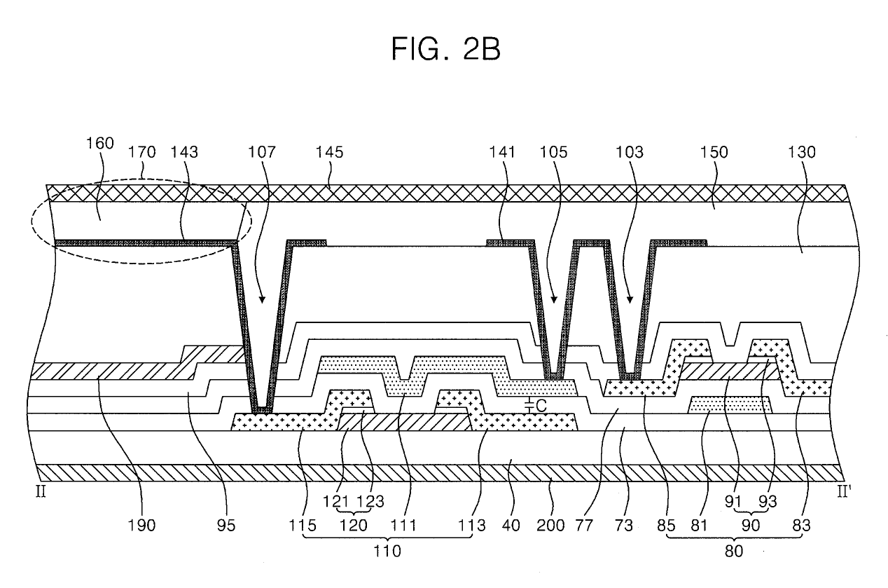

FIG. 1 is a plan view illustrating an OLED device according to one embodiment. FIGS. 2A and 2B, respectively, are cross sectional views taken along the line I-I′ and the line II-II′ of FIG. 1.

Referring to FIGS. 1 to 2B, the OLED device includes a substrate 40, a gate line 50, a data line 60, a power line 70, a switch thin film transistor (TFT) 80, a driving TFT 110, a pixel electrode 143, an organic light emitting layer 160, a common electrode 145, and an absorption layer 200.

The substrate 40, which is formed of a transparent material, has the switch TFT 80 and driving TFT 110, the pixel electrode 143, the organic light emitting layer 160, and the common electrode 145 on its top surface, and the absorption layer 200 on its bottom surface. The components may be differently arranged on the substrate 40.

A gate signal is supplied through the gate line 50 to the switch TFT 80, a data signal is supplied through the data line 60 to the switch TFT 80, and a power signal is supplied through the power line 70 to the driving TFT 110.

The switch TFT 80 turns on when a scan pulse is supplied to the gate line 50, thereby supplying the data signal to a storage capacitor C and a second gate electrode 111 of the driving TFT 110. The switch TFT 80 includes a first gate electrode 81 electrically connected to the gate line 50, a first source electrode 83 electrically connected to the data line 60, a first drain electrode 85 facing the first source electrode 83 and electrically connected to the second gate electrode and the storage capacitor C of the driving TFT 110, and a first semiconductor pattern 90 forming a channel portion between the first source electrode 83 and the first drain electrode 85. The first semiconductor pattern 90 includes a first activation layer 91 and a first ohmic contact layer 93. The first activation layer 91 overlaps the first gate electrode 81 with a second gate insulating layer 77 therebetween. The first ohmic contact layer 93 is formed on the first activation layer 91 except for the channel portion to provide an ohmic contact with the first source electrode 83 and the first drain electrode 85. The first activation layer 91 may be formed of amorphous silicon that is advantageous for on/off operations, since the switch TFT 80 requires excellent on/off properties.

The driving TFT 110 controls the current supplied from the power line 70 to an OLED 170 in response to the data signal supplied to the second gate electrode 111 to adjust the amount of emission. The driving TFT 110 includes a second source electrode 113 electrically connected through a connection electrode 141 to the first drain electrode 85 of the switch TFT 80, a second drain electrode 115 facing the second source electrode 113 and electrically connected to the pixel electrode 143 of the OLED 170, and a second semiconductor pattern 120 forming a channel portion between the source electrode 113 and the drain electrode 115. The connection electrode 141 electrically connects the first drain electrode 85 exposed through a first contact hole 103 to the second gate electrode 111 exposed through a second contact hole 105. The first contact hole 103 goes through a protective layer 95 and a planarization layer 130 to expose the first drain electrode 85, and the second contact hole 105 goes through the protective layer 95 and the planarization layer 130 to expose the second gate electrode 111.

The second semiconductor pattern 120 includes a second activation layer 121 and a second ohmic contact layer 123. The second activation layer 121 overlaps the second gate electrode 111 with a first gate insulating layer 73 therebetween. The second ohmic contact layer 123 is formed on the second activation layer 121 except for the channel portion to provide an ohmic contact with the second source electrode 113 and the drain electrode 115. The second activation layer 121 may be formed of polycrystalline silicon taking into consideration that a current will continue to flow in the driving TFT 110 during the emission of the OLED 170.

The storage capacitor C is formed by overlapping the power line 70 with the second gate electrode 111 with the first gate insulating layer 73 therebetween. The storage capacitor C serves to maintain the emission of the OLED 170 by enabling the driving TFT 110 to supply a constant current until receiving a data signal of a subsequent frame even when the switch TFT 80 turns off.

The common electrode 145 is formed to face the pixel electrode 143 with the organic light emitting layer 160 therebetween. The organic light emitting layer 160 is formed with respect to each sub pixel. The pixel electrode 143 is formed on the planarization layer 130, separately regarding each sub pixel regions, to overlap the color filter 190. The pixel electrode 143 is electrically connected to the second drain electrode 115 exposed through the third contact hole 107, and the third contact hole 107 passes through the protective layer 95 and planarization layer 130. The pixel electrode 143 may be formed of at least one of indium tin oxide (ITO), tin oxide (TO), indium zinc oxide (IZO), and indium tin zinc oxide (ITZO). The common electrode 145 may be formed of at least one of Al, Mg, Ag, and Ca that have good reflectivity and electron supplying capacity.

The color filter 190 is formed on the protective layer 95 to overlap the organic light emitting layer 160 that generates white light. The color filter 190 realizes red light, green light, and blue light using the white light. The red, green, and blue light are radiated from the color filter 190 through the substrate 40 to the outside.

The OLED 170 includes the planarization layer 130, the pixel electrode 143 formed of a transparent conductive material on the planarization layer 130, the organic light emitting layer 160 formed on the pixel electrode 143, and the common electrode 145 formed on the organic light emitting layer 160. The organic light emitting layer 160 may include a hole injection layer (HIL), a hole transport layer (HTL), an emitting layer (EML), an electron transport layer (ETL), and an electron injection layer (EIL) that are deposited on the pixel electrode 143. The EML may be formed in a single layer, double layer, or triple layer. In the double layer, two complementary color layers may be stacked to each other, and in the triple layer, a red emission layer, a green emission layer, and a blue emission layer are sequentially stacked. In the single layer, the EML emits white light alone.

The organic light emitting layer 160 emits light when a current is supplied to the common electrode 145, and the emissive light is radiated as white light toward the color filter 190 via the common electrode 145.

A barrier rib 150 is formed on the pixel electrode 143. The barrier rib 150 is formed of photo-resist materials, and therefore, may serve as an insulating layer. Also, the barrier rib 150 blocks light directed from the organic light emitting layer 160.

The absorption layer 200 may be formed on the bottom surface of the substrate 40. This absorption layer 200 absorbs cyan spectrum of light and splits it into blue light and green light when the light generated from the organic light emitting layer 160 is separated into red, green, and blue light passing through the color filter 190. Accordingly, color gamut, brightness, and efficiency may be improved.

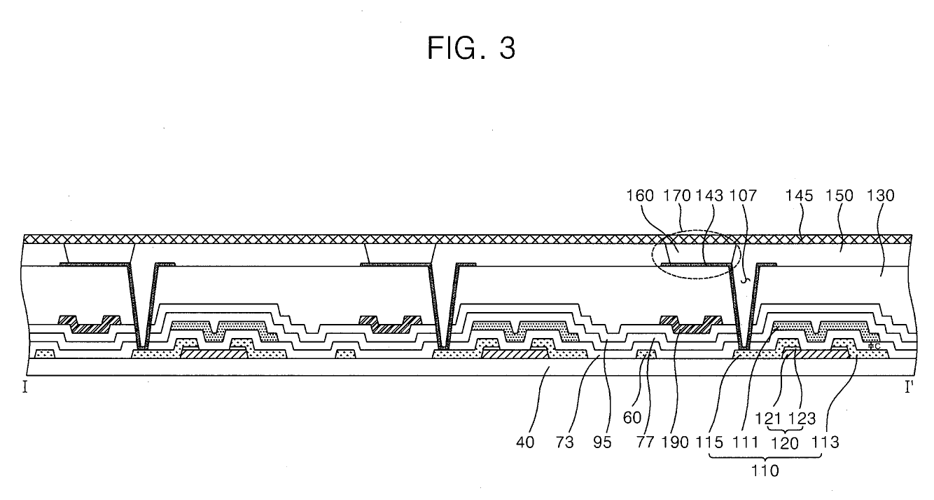

FIG. 3 is a cross sectional view taken along the line I-I′ of FIG. 1 according to another embodiment.

Referring to FIG. 3, the OLED device includes a substrate 40, a gate line, a data line 60, a switch TFT, a driving TFT 110, a pixel electrode 143, an organic light emitting layer 160, and a common electrode 145. The substrate 40 is formed to absorb the cyan spectrum of light.

The other components than the substrate 40, which is substituted for the absorption layer 200, are the same as those described in a previous embodiment, and therefore, the detailed descriptions will be omitted.

The OLED device may acquire improved color gamut as well as slim design by adding the same function as that of the absorption layer 200 to the substrate 40 without a separate absorption layer.

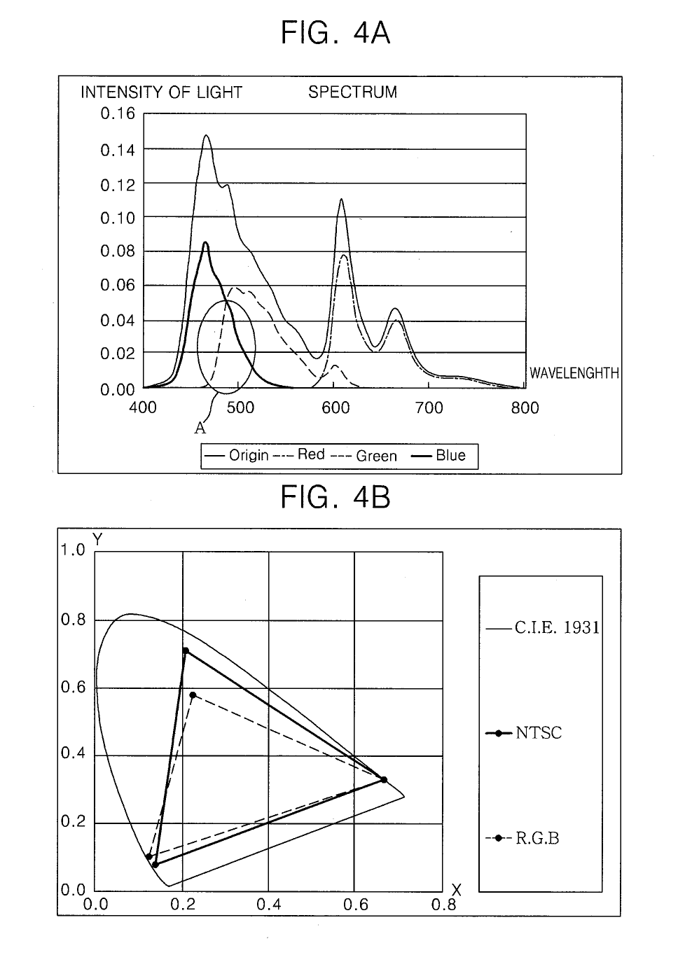

FIGS. 4A and 4B, respectively, are a graph and a chromaticity diagram illustrating spectrums and color gamut of light that has passed through a color filter.

More specifically, FIGS. 4A and 4B present the spectrums and color gamut of red, green, and blue light split while passing through red, green, and blue color filters. Arguably, the most important factor of degrading the color gamut is non-separation of blue light and green light. FIG. 4A presents a non-separation or overlapping of blue light and green light in area A. Accordingly, the color gamut is greatly lowered by the factor of 73.12% based on an NTSC (100%) chromaticity diagram as shown in FIG. 4B.

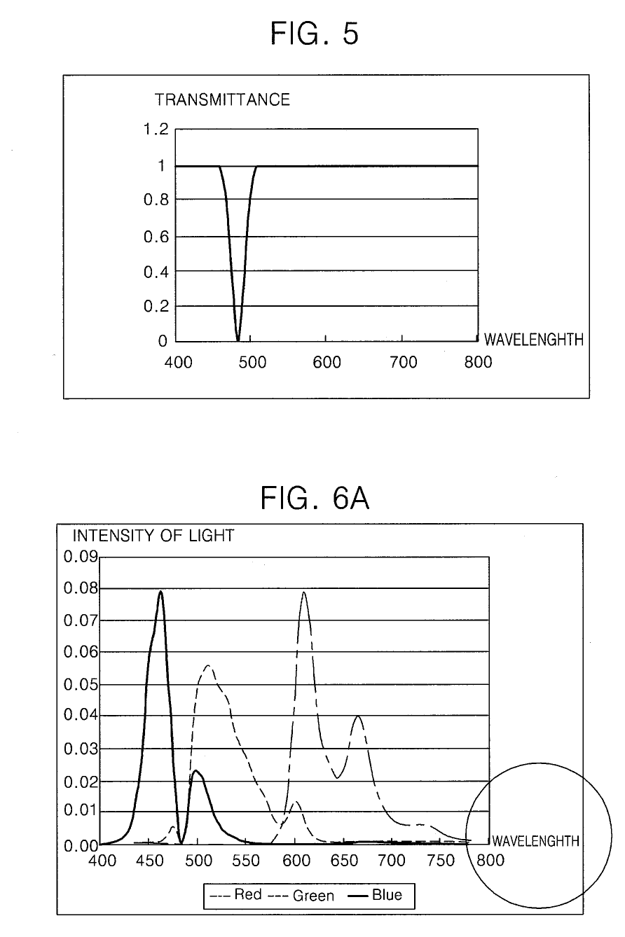

FIG. 5 is a graph illustrating a relationship of transmittance and wavelength of an absorption layer according to another embodiment.

Referring to FIG. 5, the absorption layer 200 has a wavelength area within which cyan spectrum of light can be absorbed. The wavelength area may be in the range of from about 470 nm to about 520 nm, for example, from 485 nm to 490 nm, taking into consideration the maximum absorption wavelength of the blue light is about 460 nm, the green light 530 nm. The color filter employs a pigment or dye to implement a color. Pigment using light diffusion characteristics tends to have a wide bandwidth with respect to a certain wavelength. In contrast, the dye using the light absorption characteristics tends to have a narrow wavelength with respect to a certain wavelength. In addition, a dye of absorbing cyan light may be used.

Hereinafter, a method of manufacturing an absorption layer will be schematically described.

A color substance that may absorb cyan spectrum of light includes, for example, Lumaplast Red-A2G commercially available from M-Dohmen, which has the maximum absorption wavelength around 490 nm. The maximum absorption wavelength may be tuned by adjusting the ratio of the color substance or mixing other dyes or pigments. The color substance is resolved in 1,3-dioxolane or methylketone (MEK) of 70% by weight, and then mixed with an acrylic-based binder, e.g. IR-G205, of 30% by weight thereby to form a coating composition. The coating composition is coated by a barcoater on a high molecular film that contains polyethyleneterephthalate (PET). Then, the coating composition is dried and heated to form the absorption layer. The high molecular film that is coated the coating composition may be attached to the substrate 40.

The color substance of absorbing cyan spectrum of light may be directly coated on the color filter during the process of manufacturing the OLED device without coating the coating composition on the separate high molecular film. The color substance may be formed either on the top surface of the color filter or on the bottom surface.

Hereinafter, a case will be described to evaluate the effect of the subject matter described herein, where the absorption layer follows an inverse normal distribution curve wherein the transmittance is 0 and FWHM (full width at half maximum) is 20 nm. For the reference, FWHM means “full width, half maximum,” the length over which the beam falls off half its maximum intensity.

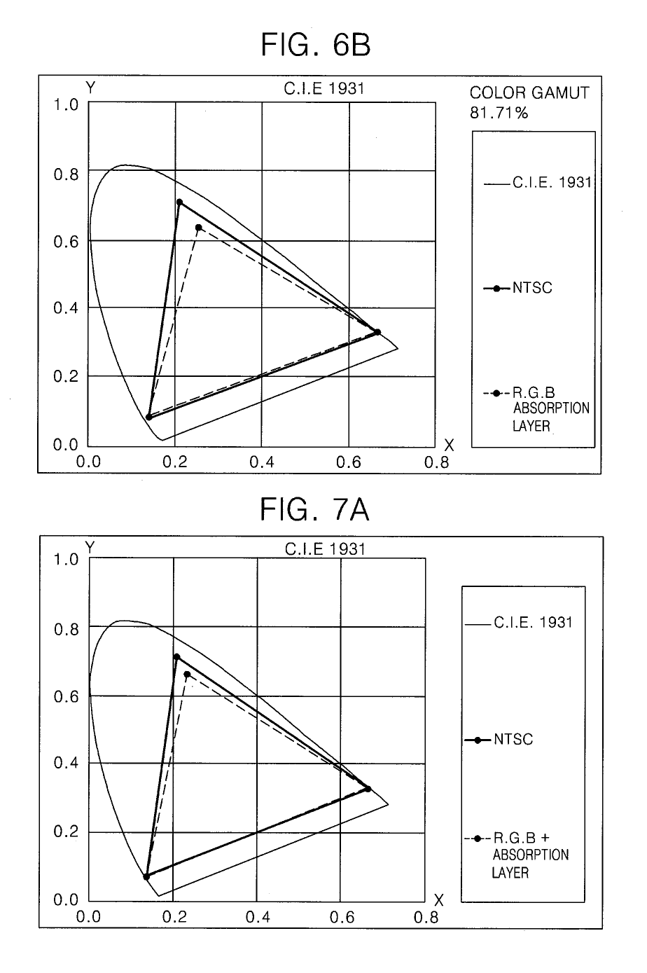

FIGS. 6A and 6B, respectively, are a graph and a chromaticity diagram illustrating spectrums and color gamut of light that has passed through a color filter and an absorption layer according to another embodiment.

Referring to FIGS. 6A and 6B, it can be seen that the color gamut can be improved by a factor of about 9%, that is, reach about 81.71%, in case of adding the absorption layer to the color filter compared to using the color filter alone.

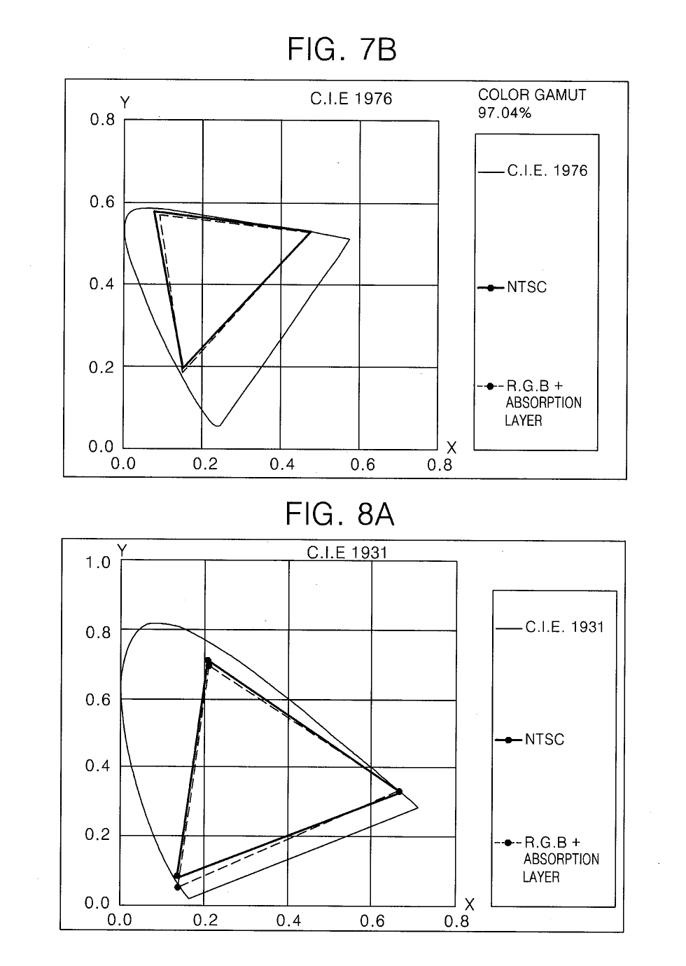

FIGS. 7A and 7B are chromaticity diagrams illustrating the brightness and efficiency of a color filter based on 90% color gamut according to another embodiment.

FIGS. 7A and 7B are consequences yielded based on 1931 NTSC standard and 1976 chromaticity diagram. As can be seen, the brightness was improved by the factor of about 11%, the efficiency about 10%, in the color gamut of 90%, compared to using the color filter alone.

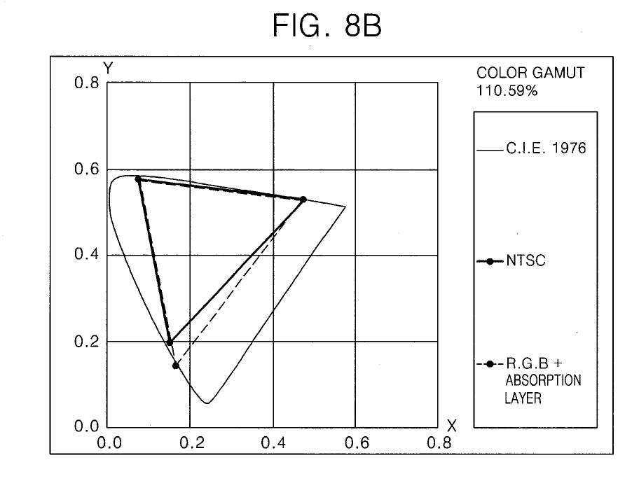

FIGS. 8A and 8B are chromaticity diagrams illustrating the brightness and efficiency of a color filter based on 100% color gamut according to another.

FIGS. 8A and 8B are consequences yielded based on 1931 NTSC standard and 1976 chromaticity diagram. As can be seen, the brightness was improved by the factor of about 28%, the efficiency about 32%, in the color gamut of 100%, compared to using the color filter alone

Although the above embodiments have focused on a case where a unit pixel consists of three colors of sub pixels, such as red, green, and blue, the present invention is not limited thereto. For example, a white sub pixel may be further added to the unit pixel.

And, although it has been described that a separate film-type absorption layer is added to the substrate, the subject matter of the disclosure is not limited thereto. For example, in various embodiments the substrate has the same function as that of the absorption layer.

As mentioned above, the various embodiments may improve color gamut by clearly splitting green spectrum of light and blue spectrum of light through an absorption layer.

The absorption layer may be provided in the form of a separate film on which a color substance of absorbing a prescribed spectrum of light has been coated, or by coating the color substance directly on the substrate of the OLED device without providing the separate film.

Although the disclosure has been described with reference to certain embodiments thereof, it will be understood by those skilled in the art that a variety of modifications and variations may be made without departing from the spirit or scope of the subject matter defined in the appended claims, and their equivalents.

What is claimed is:

1. An organic light emitting diode device comprising:
a substrate;
a switch thin film transistor on a first side of the substrate to perform a switching function and a driving thin film transistor on the first side of the substrate to perform a driving function;
a pixel electrode electrically connected to the driving thin film transistor;
a common electrode to form an electric field together with the pixel electrode, the common electrode corresponding to the pixel electrode;
an organic light emitting layer disposed between the pixel electrode and the common electrode to generate light;
a color filter overlapping the pixel electrode to convert the light generated from the organic light emitting layer into a prescribed color of light; and
an absorption layer formed on a second side of the substrate that is parallel to the first side to absorb cyan spectrum of light.

2. The organic light emitting diode device of claim 1, wherein the absorption layer absorbs light whose wavelength ranges from about 470 nm to about 520 nm.

3. The organic light emitting diode device of claim 2, wherein the absorption layer contains a dye or pigment that absorbs light whose wavelength ranges from about 470 nm to about 520 nm.

4. The organic light emitting diode device of claim 3, wherein the absorption layer is formed by attaching to the substrate a high molecular film on which the dye or pigment has been coated.

5. The organic light emitting diode device of claim 3, wherein the absorption layer is formed by coating a solution containing the dye or pigment on the substrate.

6. The organic light emitting diode device of claim 1, wherein the organic emission layer generates white light.

7. An organic light emitting diode device comprising:
a substrate formed to absorb cyan spectrum of light;
a switch thin film transistor on a first side of the substrate to perform a switching function and a driving thin film transistor on the first side of the substrate to perform a driving function;
a pixel electrode electrically connected to the driving thin film transistor;
a common electrode to form an electric field together with the pixel electrode, the common electrode corresponding to the pixel electrode;
an organic light emitting layer disposed between the pixel electrode and the common electrode to generate light; and
a color filter overlapping the pixel electrode to convert the light generated form the organic light emitting layer into a prescribed color of light.

8. The organic light emitting diode device of claim 7, wherein the substrate absorbs light whose wavelength ranges from about 470 nm to about 520 nm.

9. The organic light emitting diode device of claim 8, wherein the substrate contains a dye or pigment that absorbs light whose wavelength ranges from about 470 nm to about 520 nm.

10. The organic light emitting diode device of claim 7, wherein the organic emission layer generates white light.

11. A method of manufacturing an organic light emitting diode device, the method comprising:
forming a switch thin film transistor to perform a switching function and a driving thin film transistor to perform a driving function on a first side of a substrate;
forming a protective layer on the substrate to protect the switch thin film transistor and the driving thin film transistor;
forming a color filter on the protective layer;
forming an organic light emitting diode on the color filter, the organic light emitting diode comprising a pixel electrode electrically connected to the driving thin film transistor, an organic light emitting layer disposed on the pixel electrode to generate light, and a common electrode to form an electric field together with the pixel electrode, the common electrode corresponding to the pixel electrode; and
forming an absorption layer on a second side of the substrate facing the first side to absorb cyan spectrum of light.

12. The method of claim 11, wherein said forming the absorption layer comprises forming the absorption layer using a dye or pigment of absorbing a cyan spectrum of light.

13. The method of claim 12, wherein said forming the absorption layer comprises forming the absorption layer by attaching on the substrate a high molecular film on which the dye or pigment has been coated.

14. The method of claim 12, wherein said forming the absorption layer comprises forming the absorption layer by coating a solution containing the dye or pigment on the substrate.

15. A method of manufacturing an organic light emitting diode device comprising:
forming a substrate that absorbs a cyan spectrum of light;
forming a switch thin film transistor to perform a switching function and a driving thin film transistor to perform a driving function on a first side of the substrate;
forming a protective layer on the substrate to protect the switch thin film transistor and the driving thin film transistor;
forming a color filter on the protective layer; and
forming an organic light emitting diode on the color filter, the organic light emitting diode comprising a pixel electrode electrically connected to the driving thin film transistor, an organic light emitting layer disposed on the pixel electrode to generate light, and a common electrode to form an electric field together with the pixel electrode, the common electrode corresponding to the pixel electrode.

16. The method of claim 15, wherein said forming the substrate comprises forming the substrate by making the substrate contain a dye or pigment that absorbs a cyan spectrum of light.
